(19) United States
(12) Patent Application Publication
(10) Pub. No.: US 2025/0125287 A1
(43) Pub. Date: Apr. 17, 2025

(54) DYNAMIC RANDOM-ACCESS MEMORY DEVICES AND METHODS OF MANUFACTURING THE SAME

(71) Applicant: Winbond Electronics Corp., Taichung City (TW)

(72) Inventor: Te-Hsuan PENG, Taichung City (TW)

(21) Appl. No.: 18/789,237

(22) Filed: Jul. 30, 2024

(30) Foreign Application Priority Data
Oct. 17, 2023 (TW) 112139555

(51) Int. Cl. H01L 23/64; H10B 12/00

(52) U.S. Cl. CPC H01L 23/642; H10B 12/0335; H10B 12/37; H10B 12/482; H10B 12/485

(57) ABSTRACT

A dynamic random access memory device includes a substrate having an active area, a stacked structure and a capacitor contact structure. The stacked structure is formed over the substrate and includes a bit line structure, a mask structure and a spacer structure. The bit line structure on the substrate is electrically connected to the active area. The mask structure is formed on the bit line structure and includes the first, second and third dielectric layers that are sequentially formed on the bit line structure. The dielectric constant of the second dielectric layer is less than the dielectric constant of each of the second and third dielectric layers. The spacer structure is formed on sidewalls of the bit line structure and the mask structure. The capacitor contact structure formed on the substrate is laterally separated from the stacked structure. The capacitor contact structure is electrically connected to the active area.

### CROSS REFERENCE TO RELATED APPLICATIONS

This Application claims priority of Taiwan Patent Application No. 112139555, filed on Oct. 17, 2023, the entirety of which is incorporated by reference herein.

### BACKGROUND

### Technical Field

The disclosure relates to a dynamic random-access memory (DRAM) device and method of manufacturing the same, and in particular, it relates to a DRAM device that can reduce parasitic capacitance and improve electrical performance and method of manufacturing the same.

### Description of the Related Art

DRAM devices are widely used in consumer electronic products. To increase the integration density of various components in a DRAM device and improve its overall performance, current methods of manufacturing DRAM devices continue to develop with respect to reducing the device size. As device sizes continue to shrink, many challenges arise. For example, as the size of DRAM devices shrinks, the lateral distance between the landing pad of the capacitor and the adjacent bit line becomes closer, and the influence of parasitic capacitance between the landing pad and the bit line on the DRAM device is increased.

In addition, in the conventional DRAM devices, before the bit line material layer is formed, if a film layer that has been formed is affected by the previous processes (such as material residues, pollutants or grains in the film layer itself), undesired protrusions of the film layer may occur. The uneven film layer causes the subsequently formed bit line material layer to be raised unexpectedly. As a result, the raised bit line material layer may be exposed after the subsequent planarization process is performed. The exposed bit line material layer may be easily damaged, and the subsequently formed bit line structure would have poor structural contour or even defect of line breakage. In order to solve this problem, the thickness of the hard mask layer above the bit line material layer is increased in some conventional DRAM devices. However, when the thickness of the hard mask layer is increased, it is required to adjust the process conditions of ion implantation in the active areas of the peripheral region to achieve the desired ion implantation range and depth. The foregoing adjustment does increase process difficulty and development time. In addition, as the sizes of DRAM devices shrink, increasing the thickness of the hard mask layer may cause the subsequent ion implantation of the active areas in the peripheral region with to fail to achieve the expected ion implantation range and depth, thereby causing the failure of the peripheral circuits. Thus, increasing the thickness of the hard mask layer may reduce the yield of DRAM devices.

### SUMMARY

Some embodiments of the present disclosure provide a DRAM device. The DRAM device includes a substrate having an active area; a stacked structure that is formed over the substrate and extends in the first direction; and a capacitor contact structure that is formed on the substrate and laterally separated from the stacked structure, wherein the capacitor contact structure is electrically connected to the active area. The stacked structure includes a bit line structure, a mask structure and a spacer structure. The bit line structure is formed over the substrate and electrically connected to the active area. The mask structure is formed over the bit line structure, and includes the first dielectric layer, the second dielectric layer and the third dielectric layer sequentially formed on the bit line structure and stacked in the second direction, wherein the dielectric constant of the second dielectric layer is less than the dielectric constant of the first dielectric layer and the dielectric constant of the third dielectric layer. The spacer structure is formed on the sidewalls of the bit line structure and the mask structure.

Some embodiments of the present disclosure provide a method of manufacturing a DRAM device. The method includes providing a substrate that has an active area; forming a bit line material layer over the substrate; forming a mask material stack layer on the bit line material layer; patterning the mask material stack layer and the bit line material layer to form a stacked structure that extends in the first direction; and forming a capacitor contact structure on the substrate, wherein the capacitor contact structure is laterally separated from the stacked structure, and the capacitor contact structure is electrically connected to the active area. The stacked structure includes a bit line structure, a mask structure and a spacer structure. The bit line structure is formed over the substrate and electrically connected to the active area. The mask structure is formed over the bit line structure, and includes the first dielectric layer, the second dielectric layer and the third dielectric layer sequentially formed on the bit line structure and stacked in the second direction, wherein the dielectric constant of the second dielectric layer is less than the dielectric constant of the first dielectric layer and the dielectric constant of the third dielectric layer. The spacer structure is formed on the sidewalls of the bit line structure and the mask structure.

The DRAM device and its manufacturing method in accordance with some embodiments of the present disclosure disclose mask structures over the respective bit line structures, and each of the mask structure includes different dielectric material layers to reduce the parasitic capacitance between the landing pad of the capacitive contact structure and the bit line structure adjacent to the landing pad, thereby improving the electrical performance of the DRAM device.

### BRIEF DESCRIPTION OF THE DRAWINGS

FIG. 1 is a top view of an intermediate manufacturing stage of part of a DRAM device, in accordance with one embodiment of the present disclosure.

FIG. 2 is a cross-sectional view taken along line B-B of the DRAM device of FIG. 1.

FIG. 3, FIG. 4, FIG. 5, FIG. 6, FIG. 7, FIG. 8, FIG. 9, FIG. 10, FIG. 11 and FIG. 12 are cross-sectional views of a DRAM device at various intermediate manufacturing stages, in accordance with one embodiment of the present disclosure.

FIG. 10A is a top view of part of a DRAM device in accordance with one embodiment of the present disclosure.

FIG. 13 to FIG. 15 are cross-sectional views of a DRAM device at various intermediate manufacturing stages in accordance with some embodiments of the present disclosure.

FIG. 16 is a cross-sectional views of a DRAM device in fabrication in accordance with one embodiment of the present disclosure.

### DETAILED DESCRIPTION

The following disclosure provides many different embodiments, or examples, for implementing different features of the invention. These are, of course, merely examples and are not intended to be limiting. In addition, the formation of a first feature over or on a second feature in the description that follows may include embodiments in which the first and second features are formed in direct contact, and may also include embodiments in which the first and second features may not be in direct contact, unless otherwise specifically excluded. In addition, for the purpose of simplicity and clarity, the embodiments of the present disclosure may use the same or similar reference numerals and/or letters for the same or similar features in different embodiments. This repetition of reference numerals and/or letters does not in itself dictate a relationship between the various embodiments and/or configurations discussed. The drawings of the embodiments in the present disclosure may only show parts of an exemplified DRAM device.

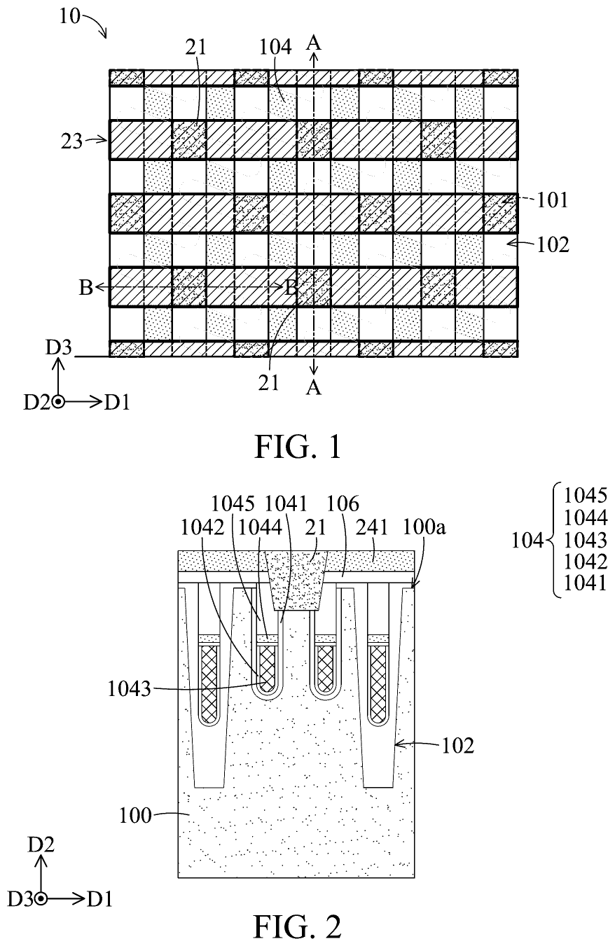

The following describes a DRAM device and a method of manufacturing the same in accordance with the present disclosure. First, please refer to FIG. 1, which is a top view of an intermediate manufacturing stage of part of a DRAM device. The array region A1 in the following figures is drawn along the line A-A of the DRAM device of FIG. 1.

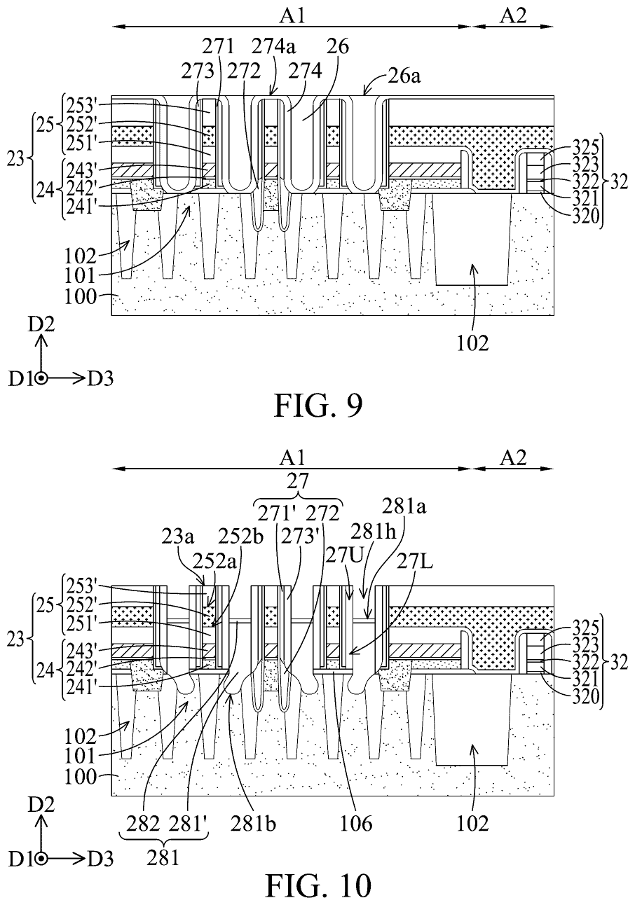

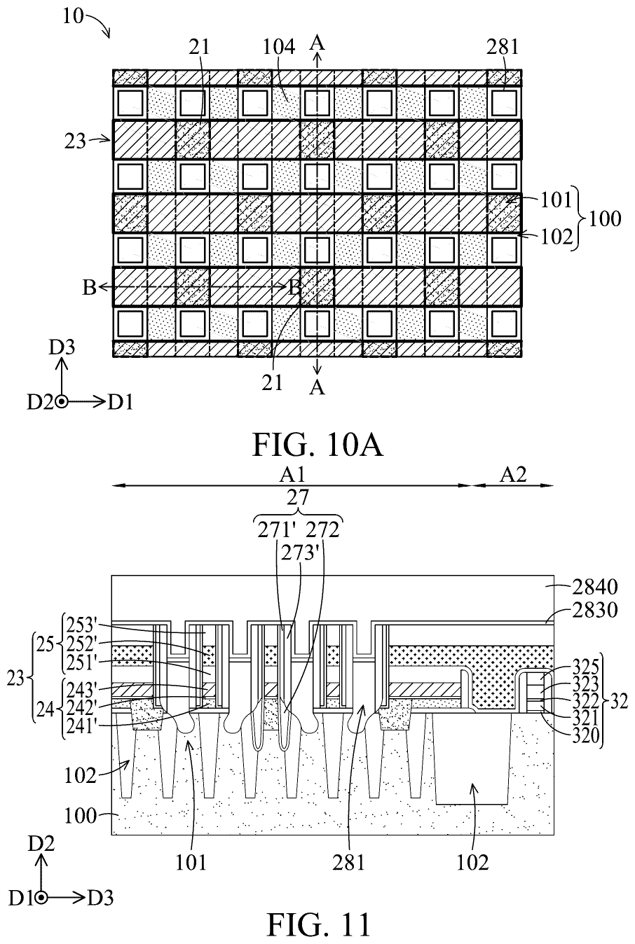

A DRAM device 10 includes a substrate 100, several word lines 104, several bit line contacts 21, several bit lines 23 and several capacitive contacts (not shown in FIG. 1, but FIG. 10A shows the positions of the node contact plugs 281 of the capacitor contacts), in accordance with an embodiment of the present disclosure. The substrate 100 includes several doping regions as active area 101. In addition, isolation structure 102 and word lines 104 may be formed in the substrate 100. The isolation structure 102 surrounds the active area 101 of the substrate 100. In some embodiments, each of the bit lines 23 includes several material layers that are stacked over the substrate 100 in the second direction D2. Each of the bit lines 23 may extend in the first direction D1, and the bit lines 23 may be arranged in the third direction D3. The first direction D1 is, for example, but not limited to, perpendicular to the second direction D2. In addition, each of the word lines 104 may extend in the third direction D3. That is, the word lines 104 may intersect with the bit lines 23, and the word lines 104 may be arranged in the first direction D1. In one embodiment, the extension direction of each of the active areas 101 may be tilted at an angle (for example, an angle in the range of about 10 degrees to 40 degrees) with respect to the third direction D3, thereby improving the integration density of related components. In some embodiments, each of the active areas 101 may intersect with two word lines 104 and one bit line 23. The active areas 101 may be electrically connected to the upper bit lines 23 through the respective bit line contacts 21. These bit line contacts 21 may be arranged in the staggered positions, as viewed from the top side of the substrate 100. In addition, the bit line contacts 21 may be alternated with the word lines 104 in the extending direction of the bit lines 23 (for example, in the first direction D1), as viewed from the top side of the substrate 100.

FIG. 2 is a cross-sectional view taken along line B-B of the DRAM device of FIG. 1. In some embodiments, the word lines 104 can be formed in the substrate 100 so that the top surfaces of the word lines 104 are lower than the top surface 100a of the substrate 100. Therefore, the word lines 104 of this embodiment can also be referred to as buried word lines. Each of the word lines 104 may include a gate dielectric layer 1041, a barrier layer 1042 and a conductive material layer 1043 formed in a sequence. The conductive material layer 1043 may include a first work function layer 1043 and a second work function layer 1044. Then, an insulating layer 1045 is formed over the word line 104 (for example, the insulating layer 1045 is formed over the second work function layer 1044).

In one embodiment, the gate dielectric layer 1041 may include silicon oxide, silicon nitride, another suitable material, or a combination of the foregoing materials. The barrier layer 1042 may include one or more conductive metals. For example, the barrier layer 1042 includes metal, metal alloy, metal nitride or metal silicide.

In some embodiments, the first work function layer 1043 is formed on the barrier layer 1042. The first work function layer 1043 may include one or more conductive metals. For example, the work function layers 1043 include metal, metal alloy, metal nitride, or metal silicide. In one embodiment, the work function layers 1043 include tungsten, tantalum, titanium, ruthenium, aluminum, tungsten nitride, titanium nitride, titanium silicon nitride, tantalum nitride, another suitable conductive material, or a combination of foregoing conductive materials.

In some embodiments, the second work function layer 1044 is formed on the first work function layer 1043. The second work function layer 1044 may include doped or undoped polysilicon, metal, metal alloy, metal nitride, metal silicide, or another suitable material. In one embodiment, the barrier layer 1042 includes titanium nitride, and the first work function layer 1043 includes tungsten. The second work function layer 1044 may include polysilicon, titanium nitride, titanium silicon nitride, tantalum nitride, tungsten nitride, tantalum, titanium, tungsten, ruthenium, aluminum, or another suitable conductive material.

It should be noted that, in some embodiments, related components and configuration of the exemplified word lines 104 shown in FIG. 2 are provided for illustrative purposes. The DRAM device 10 provided in the present disclosure may include any known word line structure and its fabrication process. The embodiments of the present disclosure are not limited to the exemplified configurations and processes.

The present disclosure provides a novel bit line stacked structure to improve the electrical performance of the DRAM device 10 (for example, the parasitic capacitance between the capacitor contact structure and adjacent bit lines of the DRAM device 10 can be reduced). Also, the problems of poor contour and even line breakage of the bit line stacked structure due to the unevenness of the film layers can be solved. In addition, the manufacturing method provided in the embodiments of the present disclosure does not affect the manufacturing process for forming other components of the DRAM device 10. For example, there is no need to change the manufacturing process of the components (such as transistor components) located in the peripheral region. Thus, it is easy to integrate the embodied method with the existing manufacturing process to manufacture the DRAM device, thereby shortening the development time of the DRAM device 10. The following is a method of manufacturing a DRAM device according to some embodiments of the present disclosure with reference to the drawings.

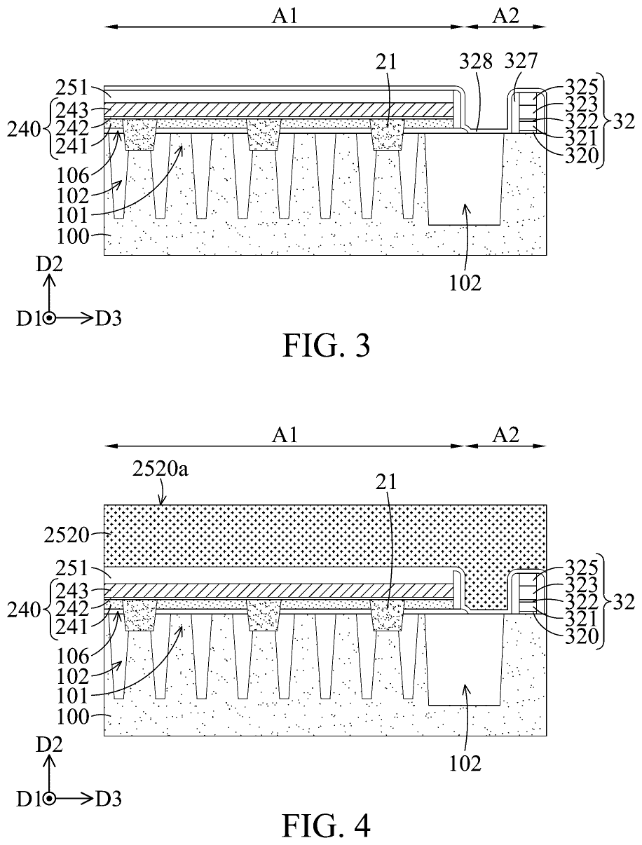

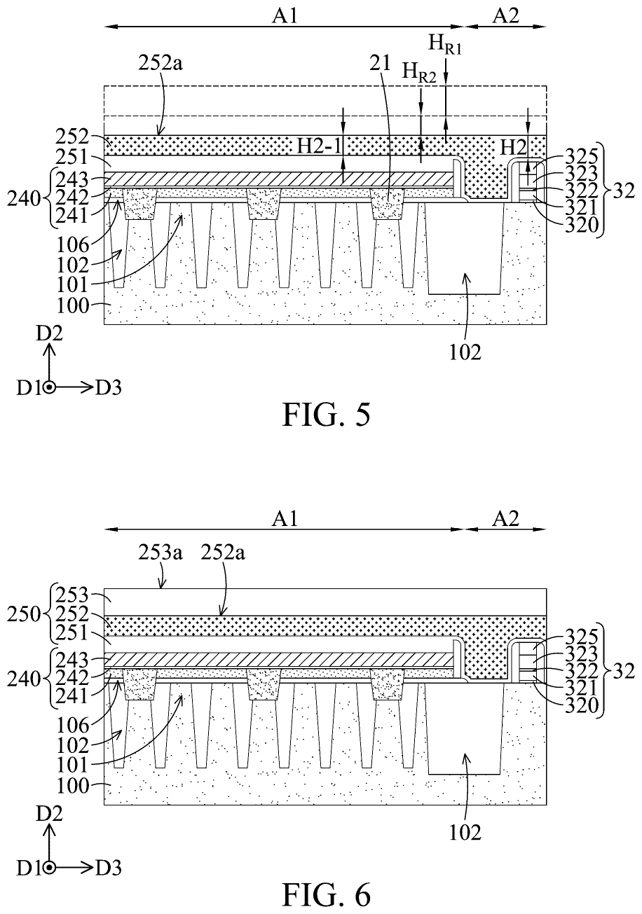

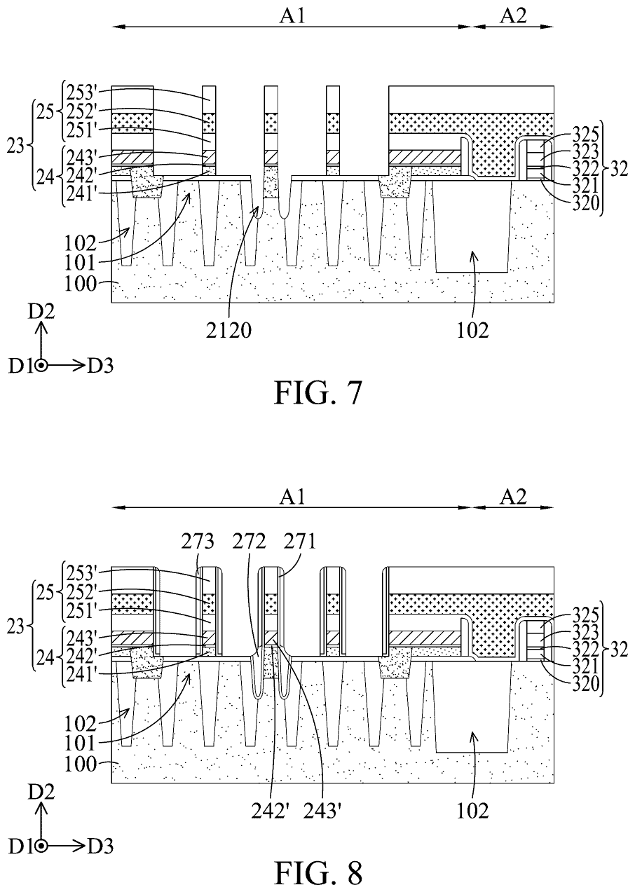

The substrate 100 may include a semiconductor material, which may include silicon, gallium arsenide, gallium nitride, germanium silicide, another suitable substrate material, or a combination of the foregoing materials. In some other embodiments, the substrate 100 is a silicon-on-insulator (SOI) substrate. In this embodiment, the substrate 100 is a silicon substrate and includes an array region A1 and a peripheral region A2 (shown in FIG. 3). In addition, when the following context describes a film layer that is formed or deposited blanketly, it means that the film layer covers both of the array region A1 and the peripheral region A2.

In some embodiments, the isolation structure 102 surrounding the active area 101 is shallow trench isolation structure. For example, the isolation structure 102 may include an isolation liner and an isolation filler formed in the sequence. The isolation liner and isolation filler may include nitrides or oxides, such as silicon oxide, silicon nitride, silicon oxynitride, and/or a combination of the foregoing materials. It should be noted that the isolation structure 102 in the drawings are provided for illustrative purposes. Any known isolation structure 102 and its manufacturing method may be used in the embodiments of the disclosure.

In addition, referring to FIG. 2, after the insulating layers 1045 is formed on the word lines 104, a dielectric material layer 106 is blanketly formed over the substrate 100, in accordance with some embodiments of the present disclosure. For example, the dielectric material layer 106 may include a nitride layer and an oxide layer that are formed sequentially, but the present disclosure is not limited thereto.

Next, referring to FIG. 3, a bit line material layer 240 and a first dielectric material layer 251 are formed over the dielectric material layer 106 in the array region A1, and several device structures 32 are formed in the peripheral region A2. In this embodiment, the bit line material layer 240 may include a semiconductor material layer 241, a first conductive material layer 242 and a second conductive material layer 243, but the disclosure is not limited thereto. In addition, the bit line contacts 21 are formed through the semiconductor material layer 241 and the dielectric material layer 106, and further extend into the substrate 100.

In some embodiments, the semiconductor material layer 241 may be an undoped semiconductor layer, a doped semiconductor layer, or a polysilicon layer. The bit line contacts 21 may include polysilicon, metal, or metal nitride. The first conductive material layer 242 and the second conductive material layer 243 may include undoped or doped polysilicon, metal, or metal nitride. For example, the first conductive material layer 242 and the second conductive material layer 243 include tungsten, titanium, or titanium nitride. The resistance of the second conductive material layer 243 may be lower than the resistance of the semiconductor material layer 241. In some embodiments, the semiconductor material layer includes polysilicon, the first conductive material layer 242 is a titanium nitride layer, and the second conductive material layer 243 is a tungsten layer.

Afterwards, a first dielectric material layer 251 is blanketly formed on the bit line material layer 240. The first dielectric material layer 251 may include nitride, another suitable dielectric material, or a combination thereof. Formation of the first dielectric material layer 251 prevents the underlying bit line material layer 240 from being damaged. In one example, the first dielectric material layer 251 includes a silicon nitride layer.

According to one embodiment, the device structure 32 is, for example, a gate stack of a transistor device. In one embodiment, the device structure 32 includes a gate oxide layer 320, a semiconductor layer 321 (such as a polysilicon layer), a first gate conductive layer 322 (such as a titanium nitride layer), a second conductive layer 323 (such as a metal tungsten layer), and a hard mask layer 325 (such as a silicon nitride layer), which are sequentially formed over the substrate 100.

In some embodiments, after the device structure 32 is formed, local implantation (not shown) that surrounds the device structure 32 is performed on the substrate 100. This local implantation can also be referred to as halo or pocket implantation to stop the expansion of the PN junction of the source/drain subsequently formed, thereby preventing breakdown of the device structure 32 with short channel. According to the embodiments of the present disclosure, since the second dielectric material layer 252 and the third dielectric material layer 253 are deposited after the device structure 32 and the local implantation are formed (as will be described in detail later with reference to FIG. 3 to FIG. 6), there is no need to adjust conditions of the local implantation. Therefore, the manufacturing method in the embodiment can achieve the advantage of reducing parasitic capacitance without affecting the processes for forming the device structure in the peripheral region A2 (details will be described below).

According to some embodiments, the spacers 327 may be formed on the sidewalls of the bit line material layer 240, the first dielectric material layer 251 and the device structure 32. In addition, source/drain regions (not shown) are formed in the substrate 100 on both sides of the device structure 32. Afterwards, a capping layer 328 is blanketly deposited over the layers and the structures on the substrate 100.

In one embodiment, the capping layer 328 may include silicon nitride. In this exemplified example, the capping layer 328 and the first dielectric material layer 251 are made of the same material, and the interface between the capping layer 328 and the first dielectric material layer 251 is omitted for the purpose of simplicity and clarity of the subsequent drawings. In addition, the reference number for labeling the capping layer 328 in the subsequent drawings is omitted.

Next, referring to FIG. 4, according to an embodiment, a second dielectric material layer 2520 for providing a flat top surface is blanketly formed on the capping layer 328. In this embodiment, the second dielectric material layer 2520 covers the first dielectric material layer 251 in the array region A1 and the device structure 32 in the peripheral region A2. The second dielectric material layer 2520 fills the gaps between the underlying components/devices. In addition, the second dielectric material layer 2520 has a sufficient thickness such that the top surface 2520a is a flat surface.

According to the present disclosure, the dielectric constant of the second dielectric material layer 2520 is less than the dielectric constant of the first dielectric material layer 251. In some embodiments, the first dielectric material layer 251 includes nitride, and the second dielectric material layer 2520 includes oxide (such as silicon oxide). In this embodiment, the second dielectric material layer 2520 includes flowable oxide to facilitate filling of the gaps that are between the components/devices under the second dielectric material layer 2520.

In some embodiments, after the second dielectric material layer 2520 is formed, the second dielectric material layer 2520 is cured by, for example, an annealing process to solidify the second dielectric material layer 2520.

Referring to FIG. 5, the second dielectric material layer 2520 that extends in the array region A1 and the peripheral region A2 is simultaneously thinned, in accordance with some embodiments of the present disclosure. The thinned second dielectric material layer 252 has a flat top surface 252a. In this embodiment, the thinned second dielectric material layer 252 may have a thickness of H2-1 in the array region A1, which is not greater than the thickness H2 of the second dielectric material layer 252 above the device structure 32 of the peripheral region A2. However, the present disclosure is not limited thereto. In an embodiment not shown, the thickness H2-1 may be greater than the thickness H2. In some embodiments, the second dielectric material layer 2520 can be thinned through a planarization process, an etching process, another suitable process, or a combination thereof. The planarization process is, for example, a chemical mechanical polishing (CMP) process. The etching process includes a dry etching process, a wet etching process, or a combination thereof. In addition, in this embodiment, the second dielectric material layer 2520 can be thinned through several stages (such as two stages). For example, the second dielectric material layer 2520 is thinned by the first thickness H_{R1} by the CMP process, and then the second dielectric material layer 2520 is thinned by the second thickness H_{R2} by the dry etching process. In some embodiments, the first thickness H_{R1} is greater than the second thickness H_{R2}. According to the aforementioned thinning steps, the thinning efficiency and flatness of the second dielectric material layer 252 can be increased.

In this embodiment, the thinned second dielectric material layer 252 will form parts of the mask structure over the bit lines in the subsequent process. In contrast, according to a conventional process, a dielectric material layer (can be referred to the second dielectric material layer of the embodiment) over a capping layer (can be referred to the capping layer of the embodiment) is planarized by using the capping layer as a stop layer for planarization. Since the top surface of the portion of the capping layer in the array region is higher than the top surface of the portion of the capping layer in the peripheral region, the portion of the capping layer in the array region can be completely removed. That is, the conventional process does not form a thinned second dielectric material layer on the capping layer in the array region.

Next, referring to FIG. 6, a third dielectric material layer 253 that include the material different from the second dielectric material layer 2520 is formed on the thinned second dielectric material layer 252. In a preferred embodiment, the thickness of the thinned second dielectric material layer 252 is less than or equal to the thickness of the third dielectric material layer 253. In addition, the dielectric constant of the second dielectric material layer 2520 is less than the dielectric constant of the third dielectric material layer 252. Accordingly, the flatness of the top surface 253a of the third dielectric material layer 253 can be improved, the underlying layers and components can be further protected, and the parasitic capacitance between the subsequently formed conductive material layer 284 and the second conductive layer 243′ (as shown in FIG. 12) can be reduced. However, the present disclosure is not limited thereto. In some embodiments, the first dielectric material layer 251, the second dielectric material layer 252 and the third dielectric material layer 253 are collectively referred to as a mask material stack layer 250 on the bit line material layer 240. In addition, in some embodiments, the thickness of the thinned second dielectric material layer 252 can be one-half to four-fifths of the thickness of the third dielectric material layer 253. However, the present disclosure is not limited thereto.

In addition, according to the embodiments of the present disclosure, the third dielectric material layer 253 and the second dielectric material layer 252 include different materials. For example, the second dielectric material layer 252 is a silicon oxide layer, and the third dielectric material layer 253 is a silicon nitride layer. In some embodiments, the third dielectric material layer 253 and the first dielectric material layer 251 include the same material. For example, the third dielectric material layer 253 and the first dielectric material layer 251 are silicon nitride layers.

Next, referring to FIG. 7, in the present embodiment, the mask material stack layer 250 and the bit line material layer 240 are patterned by using a suitable patterning process, so as to form several mask structures 25 and bit line structures 24 in the array region A1. In the descriptions of the embodiments, the mask structures 25 and the bit line structures 24 can be collectively referred to as stacked structure 23.

More specifically, in some embodiments, the mask material stack layer 250 may be first subjected to a patterning process to form several mask structures 25. Each of the mask structures 25 includes the third dielectric layer 253′, the second dielectric layer 252′ and the first dielectric layer 251′. Next, a suitable patterning process is performed on the underlying bit line material layer 240 according to the mask structures 25 to several bit line structures 24. Each of the bit line structures 24 includes the second conductive layer 243′, the first conductive layer 242′ and the semiconductor material layer 241′.

In addition, in some embodiments, as shown in FIG. 7, the patterning processes for forming the stacked structures 23 also remove portions of the bit line contacts 21 and portions of the substrate 100 adjacent to the bit line contacts 21, thereby forming recesses 212 that surround the respective bit line contacts 21. Each of the recesses 212 exposes parts of the active areas 101 and parts of the isolation structures 102.

Referring to FIG. 8, in some embodiments, a first spacer material layer 271 may be conformally formed on the sidewalls of the stacked structures 23 and the surfaces of the recesses 212, and a second spacer material layer 272 may be formed to fill the recesses 212, and the third spacer material layer 273 is conformally formed on the first spacer material layer 271. In some embodiments, the first spacer material layer 271, the second spacer material layer 272 and the third spacer material layer 273 may each include, for example, silicon oxide, silicon nitride, another suitable dielectric material, or a combination of the foregoing materials. For example, the first spacer material layer 271 and the second spacer material layer 272 are silicon nitride layers, and the third spacer material layer 273 is a silicon oxide layer, but the present disclosure is not limited thereto.

Next, referring to FIG. 9, in some embodiments, a fourth spacer material layer 274 is conformally formed on the third spacer material layer 273, and an oxide layer 26 is formed on the fourth spacer material layer 274 to fill the gaps. A planarization process may be performed on the fourth spacer material layer 274 and the oxide layer 26, such that the top surface 274a of the fourth spacer material layer 274 is level with the top surface 26a of the oxide layer 26. The fourth spacer material layer 274 may include, for example, silicon oxide, silicon nitride, another suitable dielectric material, or a combination of the foregoing materials. In some embodiments, the fourth spacer material layer 274 and the third spacer material layer 273 may include different materials. For example, the fourth spacer material layer 274 is a silicon nitride layer.

Next, referring to FIG. 10A and FIG. 10, in the present embodiment, the oxide layer 26 between the stacked structures 23 and the horizontal portions of the fourth spacer material layer 274 are removed to form node contact holes 281h exposing the substrate 100. In one embodiment, the exposed substrate 100 may be further etched so that the node contact holes 281hextend downward to be under the dielectric material layer 106. The array region A1 in FIG. 10 is a cross-sectional view taken along line A-A of FIG. 10A.

In some embodiments, after the node contact holes 281h are formed, an over-etching may be performed so that the top surfaces of the third dielectric layers 253′, the first spacer material layers 271′, the third spacer material layers 273′ and the fourth spacer material layers 274′ are coplanar. In this embodiment, the first spacer material layers 271′, the third spacer material layers 273′ and the fourth spacer material layers 274′ are collectively referred to as the bit line spacer structures 27.

Next, in some embodiments, several node contact plugs 281 are formed in the respective node contact holes 281h. Each of the node contact plugs 281 is formed on one side of the stacked structure 23 and in contact with the active area 101. The top surface 281a of the node contact plug 281 is lower than the top surface 23a of the stacked structure 23. In some embodiments, the top surface 281a of the node contact plug 281 may be positioned at a height level that is between the top surface 252a and the bottom surface 252b of the second dielectric layer 252′. For example, the top surface 281a of the node contact plug 281 may be close to or equal to a height level of the bottom surface 252b of the second dielectric layer 252′ of the mask structure 25, but the present disclosure is not limited thereto. In some embodiments, the conductive material for forming the node contact plugs 281 includes, for example, doped polysilicon, metal, metal nitride, metal silicide, or a combination of the foregoing materials. In this embodiment, each of the node contact plugs 281 includes a doped polysilicon layer 281′ and a metal silicide layer 282 (for example, cobalt silicon (CoSi)) that are formed sequentially. The metal silicide layer 282 decreases the contact resistance between the doped polysilicon layer 281′ and the landing pad formed in the subsequent process.

According to some embodiments, the bit line spacer structure 27 may include the upper portion 27U and the lower portion 27L. The upper portion 27U is positioned higher than the height level of the top surface 281a of the node contact plug 281. The lower portion 27L is positioned lower than the height level of the top surface 281a of the node contact plug 281. Each node contact plug 281 has a bottom surface 281b that may be beneath the dielectric material layer 106.

Next, referring to FIG. 11, in some embodiments, a barrier material layer 2830 is conformally formed on the mask structures 25 and the node contact holes 281h in which the node contact plugs 281 are formed. Then, a conductive material layer 2840 is formed on the barrier material layer 2830 in an excess amount. The barrier material layer 2830 may include metal nitride, such as titanium nitride. The conductive material layer 2840 may include doped polysilicon, metal, or metal nitride, such as metal tungsten.

Next, referring to FIG. 12, in the present embodiment, portions of the barrier material layer 2830 and portions of the conductive material layer 2840 are removed to form landing pads. The landing pad 285 includes the barrier layer 283 and the conductive layer 284. Next, the insulating layers 291 are formed between two adjacent landing pads 285. In some embodiments, the lower portion 2851 of the landing pad 285 abuts the upper portion 27U of the spacer structure 27. The upper portion 2852 of the landing pad 285 is positioned above the third dielectric layer 253′. The node contact plugs 281 are electrically connected to capacitors that are subsequently formed by the respective landing pads 285. The landing pad 285 and the node contact plugs 281 can be collectively referred to as capacitor contact structures 280. The capacitor contact structure 280 is electrically connected to the active area 101. In this embodiment, the insulating layers 291 may include but not limited to silicon nitride.

In addition, in some embodiments, after portions of the barrier material layer 2830 and portions of the conductive material layer 2840 are removed, an over-etching step may be performed to remove portions of the third dielectric layer 253′ and portions of the spacer structures 27, such that the smallest distance between the subsequently formed insulating layer 291 and the top surface 252a of the second dielectric layer 252′ is less than the greatest thickness of the third dielectric layer 253′. In addition, the insulating layer 291 and the third dielectric layer 253′ can be made of the same material (such as silicon nitride), so that the insulating layers 291 can compensate for the removed portions of the third dielectric layer 253′. Accordingly, the bit line structures 24 can be separated from the landing pads 285 by a composite dielectric structure that includes different dielectric materials in a stack. In this embodiment, the composite dielectric structures that are positioned between the bit line structures 24 and the landing pads 285 may include a nitride layer (can be referred to as the first dielectric layer 251′), an oxide layer (can be referred to as the second dielectric layer 252′) and another nitride layer (can be referred to as the third dielectric layer 253′ or the insulating layer 291).

In a preferred embodiment, the bottom surface 285b of the lower portion 2851 of the landing pad 285 is positioned at the height level that is not lower than the bottom surface 252b of the second dielectric layer 252′ of the mask structure 25, thereby further reducing the parasitic capacitance between the landing pad 285 and the bit line structure 24. In addition, in order to control the impedance of the capacitor contact structure 280 in a better range, the bottom surface 285b of the lower portion 2851 of the landing pad 285 may be positioned at a height level that is between the top surface 252a and the bottom surface 252b of the second dielectric layer 252′.

After the capacitor contact structures 280 are formed, additional components such as capacitors, the metal layers, etc. may be formed to complete the fabrication of the DRAM device. It should be noted that in the above embodiments or their modified embodiments, one or more steps of the aforementioned processes may include one or more other known applicable steps. In order to simplify the drawings and clearly illustrate the embodiments, the drawings and detailed descriptions of these known processes are omitted herein.

The DRAM device of the present disclosure has many advantages. For example, the parasitic capacitance between the landing pad 285 of the capacitor contact structure 280 and the laterally adjacent bit line structure 24 as mentioned above can be reduced. In addition, uneven defects in the film layer (which are caused by pollutants or particles in the film layer) would lead to local protrusions of the film layer, and may cause problems with poor configuration or even disconnection of subsequently formed bit lines. The aforementioned problem can be solved by using the embodied DRAM device. One example is provided below and explained with respect to the figures.

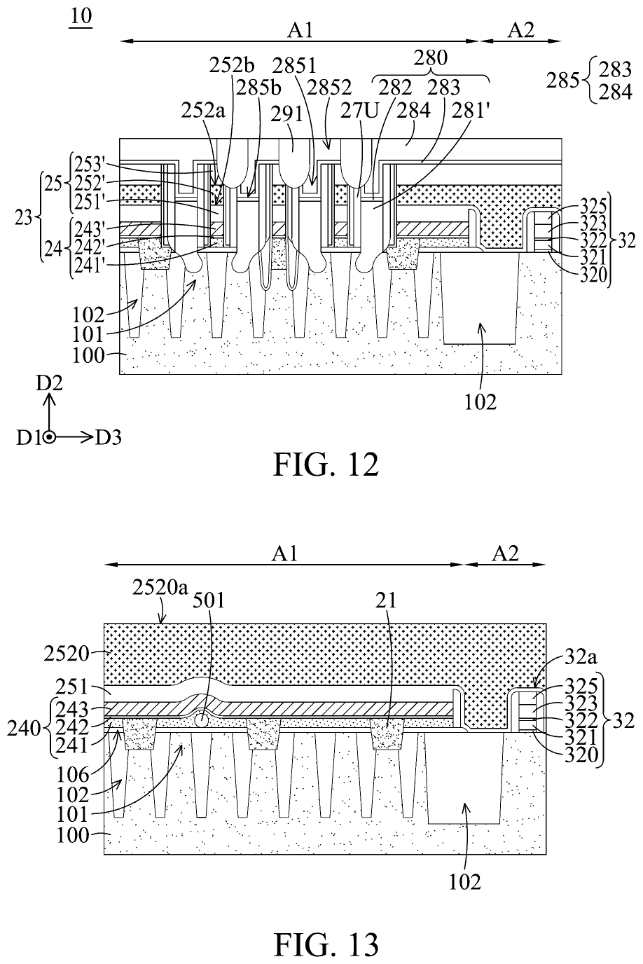

FIG. 13 to FIG. 15 are cross-sectional views of a DRAM device at various intermediate manufacturing stages in accordance with some embodiments of the present disclosure. To briefly describe the embodiment, the features/components in FIG. 13 to FIG. 15 that are similar or identical to the features/components in FIGS. 1-6 and FIG. 12 and the fabrication processes for forming those features/components are not repeated herein for the sake of simplicity and clarity.

According to some embodiments, in the manufacturing steps before formation of the second dielectric material layer 2520, contaminants (such as residual particles of nitride or oxide) may fall on the surface of the deposited layer, which causes bumps of the layer(s) formed subsequently on the contaminants. In some other cases, the material of the layer itself has grains with larger grain size, and those particles may bulge and cause bumps of the layer(s) formed subsequently on the larger particles. Referring to FIG. 13, it illustrates that a particle 501 falls on the substrate 100, and the films covering the particle 501 include, for example, the semiconductor material layer 241, the first conductive material layer 242 and the second conductive material layer 243. These films are conformally formed over the substrate 100 and have bumps above the particle 501 protruding upwardly. According to some embodiments, the second dielectric material layer 2520 that is formed on the first dielectric material layer 251 can provide a flat top surface 2520a, and reduce the effect of bumps on the flatness of deposited layers.

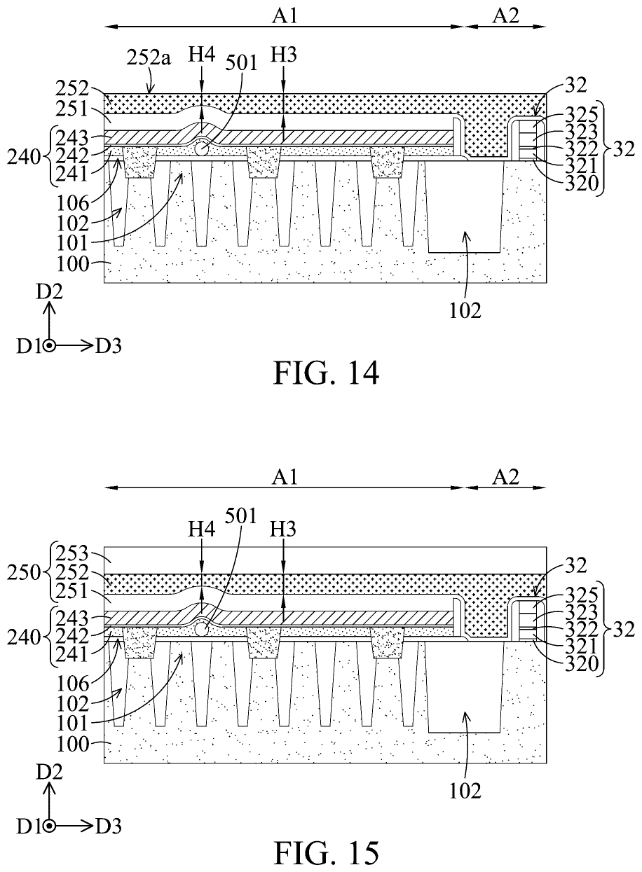

Next, referring to FIG. 14, a portion of the second dielectric material layer 2520 is removed, so that the thinned second dielectric material layer 252 has a flat top surface 252a.

In the conventional fabrication, the planarization process is performed until a dielectric layer (such as the first dielectric material layer 251 of the embodiment) on the bit line structure is exposed. If the first dielectric material layer 251 has local bump(s) above the particle 501, the underlying bit line material layer (such as the second conductive material layer 243, and may include a tungsten layer) that is conformally deposited may be exposed after the planarization process is performed. After the planarization process, one or more cleaning processes are performed. If the tungsten layer is exposed, the cleaning solution may react with the tungsten, or even diffuse outwardly to damage to a larger area of the tungsten layer. Accordingly, the subsequently formed bit line structure may have poor contours and defective configuration. In severe cases, the bit lines may break due to the damage to the exposed tungsten layer.

According to the DRAM device and the manufacturing method thereof provided in some embodiments of the present disclosure, the thinned second dielectric material layer 252 has different thicknesses H3 and H4. The thickness H4 is less than the thickness H3, and the position of the thickness H4 corresponds to the position of the particle 501, thereby further preventing the second conductive material layer 243 from being exposed. In some examples, the thickness H4 is greater than or equal to 0 nm. Accordingly, the second dielectric material layer 252 of the present disclosure provides a buffer space for the uneven film layers, thereby preventing defects such as poor contours or even line breakage of the bit line structure 24B.

Referring to FIG. 15, in some embodiments, after the second dielectric material layer 252 is formed, a third dielectric material layer 253 is formed on the second dielectric material layer 252.

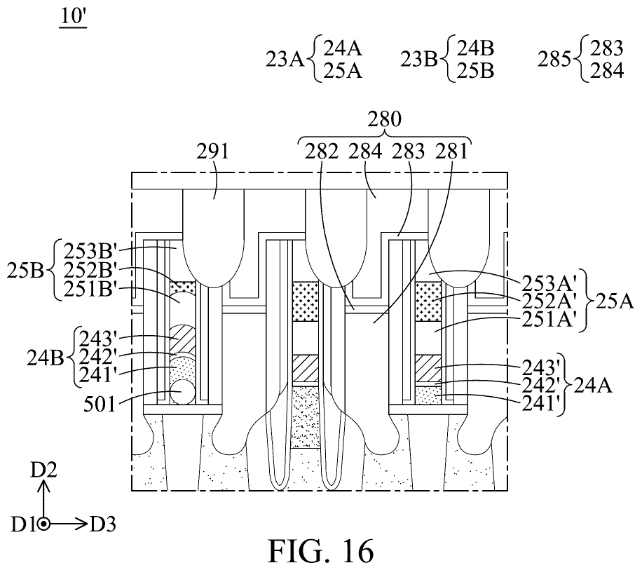

In the actual fabrication for forming the DRAM device, there may be parts with particles 501 and parts without particles 501 in the same bit line (that is, in a stacked structure). FIG. 16 shows the cross-sections of different bit lines, including the position of one bit line that contains a particle 501 and the position of another bit line that does not contains particles, to facilitate illustrating how the mask structure of the embodiment provides buffer space for the possible presence of particles 501 in the film layer.

In some embodiments of the present disclosure, the stacked structures of the DRAM device may include different mask structures. As shown in FIG. 16, the DRAM device 10′ may include a first stacked structure 23A that includes flat film layers, and a second stacked structure 23B that includes uneven film layers. A particle 501 is embedded in the second stacked structure 23B. More specifically, the first stacked structure 23A includes a first bit line structure 24A and a first mask structure 25A on the first bit line structure 24A. The first mask structure 25A includes the first dielectric layer 251A′ (such as a nitride layer), the second dielectric layer 252A′ (such as an oxide layer), and the third dielectric layer 253A′ (such as a nitride layer). In addition, the second stacked structure 23B includes the second bit line structure 24B and the second mask structure 25B on the second bit line structure 24B. The second mask structure 25B includes the fourth dielectric layer 251B′ (such as a nitride layer), the fifth dielectric layer 252B′ (such as an oxide layer), and the sixth dielectric layer 253B′ (such as a nitride layer). The first bit line structure 24A and the second bit line structure 24B each include the second conductive layer 243′, the first conductive layer 242′ and the semiconductor material layer 241′. The structural difference between the first bit line structure 24A and the second bit line structure 24B is that the layers of the second bit line structure 24B have uneven (e.g., convex) top surfaces, while the layers of the first element line structure 24A have flat top surfaces.

In some embodiments, the thickness of the fifth dielectric layer 252B′ in the second mask structure 25B is different from the thickness of the second dielectric layer 252A′ of the first mask structure 25A. For example, the thickness of the fifth dielectric layer 252B′ may be less than the thickness of the second dielectric layer 252A′.

In addition, in one embodiment that is not illustrated by drawings, the first mask structure 25A and the second mask structure 25B may have dielectric combinations with different numbers of dielectric material layers. For example, the second mask structure 25B above the particle 501 may only have the fourth dielectric layer 251B′ and the sixth dielectric layer 253B′, and does not have the fifth dielectric layer 252B′ (that is, the thickness H4=0).

According to the manufacturing method provided in the embodiment, the second dielectric material layer 252 of the mask material stack layer 250 can provide a buffer space for uneven film layers, therefore the bit line structures formed in some embodiments of the present disclosure have good structural contours, regardless of whether the dielectric combinations of the mask structures have oxide layers in the same thickness or have the same number of dielectric material layers.

According to the DRAM devices and the methods of manufacturing the DRAM devices in the embodiments of the present disclosure, the hybrid mask structures each having different dielectric materials (such as nitride layer-oxide layer-nitride layer) are formed on the respective bit line structures. The hybrid mask structures can reduce the parasitic capacitance between the landing pad of the capacitor contact structure and the laterally adjacent bit line structure, thereby improving the electrical performance and yield of the DRAM device. In addition, according to the manufacturing method provided in some embodiments, it can also solve the unevenness problem of the film layers in the traditional manufacturing process (such as contaminants or grains in the film layer itself) that causes poor structural contour or even broken line of the bit line structures. Therefore, the bit line structures with good contours can be formed, thereby improving the yield of the produced DRAM device. In addition, according to the manufacturing method provided in the present disclosure, it is simple and compatible with current manufacturing processes, which is suitable for mass production. For example, the manufacturing method provided in the embodiments of the disclosure can achieve the above-mentioned beneficial effects of reducing parasitic capacitance and forming good bit line structures without affecting the process for forming the original components of the peripheral region A2 (for example, without changing the conditions of the annular implantation of the MOS structure). Therefore, the DRAM device and its manufacturing method of the embodiments can achieve several benefits, such as reducing parasitic capacitance, forming well-contour bit line structures, and shortening time for developing the product with good yield, without increasing production costs.

In addition, the present disclosure is suitable for manufacturing miniaturized DRAM devices, thereby increasing a total number of dies on a wafer. Therefore, the present disclosure can reduce the production cost and energy consumption of manufacturing a single integrated circuit (IC) device, and reduce the production energy consumption of subsequent packaging. Accordingly, carbon emissions caused by the production process of each unit of the DRAM device can be reduced. In addition, since the yield of the DRAM device and its manufacturing method of the embodiments are improved, there is less waste in the manufacturing process. Thus, the present disclosure provides a green semiconductor technology.

What is claimed is:

1. A dynamic random-access memory (DRAM) device, comprising:
a substrate that comprises an active area;
a stacked structure that is formed over the substrate and extends in a first direction, the stacked structure comprising:
a bit line structure that is formed over the substrate and electrically connected to the active area;
a mask structure that is formed over the bit line structure, wherein the mask structure comprises a first dielectric layer, a second dielectric layer and a third dielectric layer sequentially formed on the bit line structure 9 and stacked in a second direction, wherein a dielectric constant of the second dielectric layer is less than a dielectric constant of the first dielectric layer and a dielectric constant of the third dielectric layer; and a spacer structure that is formed on sidewalls of the bit line structure and the mask structure; and
a capacitor contact structure that is formed on the substrate and laterally separated from the stacked structure, wherein the capacitor contact structure is electrically connected to the active area.

2. The DRAM device as claimed in claim 1, wherein the first dielectric layer and the third dielectric layer each include nitride, and the second dielectric layer includes oxide.

3. The DRAM device as claimed in claim 1, wherein the capacitor contact structure comprises:
a node contact plug positioned on one side of the stacked structure and in contact with the active area; and
a landing pad formed over the node contact plug, wherein a bottom surface of a lower portion of the landing pad is not lower than a bottom surface of the second dielectric layer, and an upper portion of the landing pad is formed on the third dielectric layer.

4. The DRAM device of claim 3, wherein the bottom surface of the lower portion of the landing pad is at a height level between a top surface and the bottom surface of the second dielectric layer.

5. The DRAM device of claim 3, wherein a top surface of the node contact plug is lower than a top surface of the second dielectric layer of the mask structure.

6. The DRAM device as claimed in claim 1, wherein the bit line structure comprises:
a semiconductor material layer over the substrate;
a first conductive layer on the semiconductor material layer; and
a second conductive layer on the first conductive layer, and a resistance of the second conductive layer is lower than a resistance of the semiconductor material layer,
wherein the second conductive layer and the second dielectric layer are separated by the first dielectric layer.

7. The DRAM device of claim 1, wherein the stacked structure comprises a first part and a second part, and the mask structure of the second part and the mask structure of the first part have different dielectric combinations.

8. The DRAM device of claim 1, wherein the stacked structure comprises a first part and a second part, and the second dielectric layer of the mask structure of the second part and the second dielectric layer of mask layer of the first part have different thicknesses.

9. The DRAM device of claim 1, wherein a thickness of the second dielectric layer of the mask structure is less than or equal to a thickness of the third dielectric layer of the mask structure.

10. A method of manufacturing a DRAM device, including:
providing a substrate that comprises an active area;
forming a bit line material layer over the substrate;
forming a mask material stack layer on the bit line material layer;
patterning the mask material stack layer and the bit line material layer to form a stacked structure that extends in a first direction, wherein the stacked structure comprises:
a bit line structure that is formed over the substrate and is electrically connected to the active area;
a mask structure that is formed over the bit line structure, wherein the mask structure comprises a first dielectric layer, a second dielectric layer and a third dielectric layer sequentially formed on the bit line structure and stacked in a second direction, wherein a dielectric constant of the second dielectric layer is less than a dielectric constant of the first dielectric layer and a dielectric constant of the third dielectric layer; and a spacer structure that is formed on sidewalls of the bit line structure and the mask structure; and
forming a capacitor contact structure on the substrate, wherein the capacitor contact structure is laterally separated from the stacked structure, wherein the capacitor contact structure is electrically connected to the active area. 20

11. The method of manufacturing the DRAM device as claimed in claim 10, wherein forming the mask material stack layer on the bit line material layer comprises:
forming a first dielectric material layer on the bit line material layer, wherein the first dielectric material layer comprises nitride;
forming a second dielectric material layer on the first dielectric material layer, wherein the second dielectric material layer includes oxide;
thinning the second dielectric material layer so that the thinned second dielectric material layer has a flat top surface; and
forming a third dielectric material layer on the thinned second dielectric material layer, wherein the third dielectric material layer includes nitride.

12. The method of manufacturing the DRAM device as claimed in claim 11, wherein thinning the second dielectric material layer comprises:
thinning the second dielectric material layer to remove a portion of the second dielectric material layer in a first thickness using a polishing process; and
thinning the second dielectric material layer to remove a portion of the second dielectric material layer in a second thickness via dry etching,
wherein the first thickness is greater than the second thickness.

13. The method of manufacturing the DRAM device as claimed in claim 10, wherein forming the capacitor contact structure comprises:
forming a node contact plug adjacent to a lower portion of the spacer structure,
wherein a bottom of the node contact plug is in contact with the active area, and a top surface of the node contact plug is lower than a top surface of the stacked structure; and
forming a landing pad on the node contact plug, wherein the landing pad is adjacent to an upper portion of the spacer structure, and a bottom surface of a lower portion of the landing pad is not lower than the bottom surface of the second dielectric layer, and an upper portion of the landing pad is formed on the third dielectric layer.

14. The method of manufacturing the DRAM device as claimed in claim 13, wherein the bottom surface of the lower portion of the landing pad is at a height level between a top surface and the bottom surface of the second dielectric layer.

15. The method of manufacturing the DRAM device as claimed in claim 13, wherein the top surface of the node contact plug is lower than a top surface of the second dielectric layer.

16. The method of manufacturing the DRAM device as claimed in claim 10, wherein a thickness of the second dielectric layer of the mask structure is less than or equal to a thickness of the third dielectric layer of the mask structure.
